(19) United States
(12) Patent Application Publication
(10) Pub. No.: US 2008/0272825 A1
(43) Pub. Date: Nov. 6, 2008

(54) SELECTION CIRCUIT

(75) Inventor: Yoshinori MIYADA, Yokohama-shi (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki (JP)

(21) Appl. No.: 12/112,546

(22) Filed: Apr. 30, 2008

(30) Foreign Application Priority Data
May 1, 2007 (JP) 2007-120805

(51) Int. Cl. H03K 17/00

(52) U.S. Cl. 327/408; 327/407

(57) ABSTRACT

A selection circuit includes a first switching unit that selects and outputs a first signal from among a plurality of analog signals input thereto; a second switching unit that outputs a second signal from a reference voltage supplied therein; and an amplifier that adds the first signal and the second signal.

### CROSS-REFERENCE TO RELATED APPLICATIONS

This application is based upon and claims the benefit of priority from the prior Japanese Patent Application No. 2007-120805, filed on May 1, 2007, the entire contents of which are incorporated herein by reference.

### BACKGROUND

1.Field

The embodiments discussed herein are directed to a technology of a selection circuit for analog signals.

2. Description of the Related Art

FIG. 1 is a schematic of a conventional selection circuit. Here, three analog signals are assumed to be input. The conventional selection circuit includes a first to a third input terminal (IN1 to IN3) 1 to 3, a first switch group 4 including a first to a third switch 10 to 12, a second switch group 5 including a fourth to a sixth switch 13 to 15, a differential input amplifier 7, an input resistor group 6 including a first to a third input resistor 16 to 18 of the differential input amplifier 7, a feedback resistor 8 of the differential input amplifier 7, and an output terminal 9.

The first input terminal (IN1) 1 is connected to the first input resistor 16 through the first switch 10, and to an inverting input terminal of the differential input amplifier 7 through the first input resistor 16. A first path between the first switch 10 and the first input resistor 16 is connected to an analog reference voltage source SG through the fourth switch 13. The first and the fourth switches 10 and 13 are controlled by a first signal S1 and an inverted signal XS1 of the first signal S1. The first and the fourth switches 10 and 13 exclusively become closed, i.e., conduction-state.

The second and the fifth switches 11 and 14, and the second input resistor 17 are connected on a second path between the second input terminal (IN2) 2 and the inverting input terminal of the differential input amplifier 7. The third and the sixth switches 12 and 15, and the third input resistor 18 are connected on a third path between the third input terminal (IN3) 3 and the inverting input terminal of the differential input amplifier 7.

The output terminal of the differential input amplifier 7 is connected to the output terminal (OUT) 9. The feedback resistor 8 is connected between the output terminal and the inverting input terminal of the differential input amplifier 7.

As shown in FIG. 1, when the first, the fifth, and the sixth switches 10, 14 and 15 are closed, and the second, the third, and the fourth switches 11, 12 and 13 are open, the selection circuit selects a signal sv1 to be input to the first input terminal (IN1) 1. The signal sv1 passes through the first path, and is inversely amplified at a gain determined based on the first input resistor 16 and the feedback resistor 8, and output to the output terminal (OUT) 9.

The second and the third paths are respectively connected to corresponding voltage sources SG having a conduction resistance much lower than the impedance of a noise source. As a result, noise leaking into the second and the third paths through parasitic elements of the second and the third switches 11 and 12 flow into the corresponding signal grounds having low impedance, thereby preventing the noise from affecting the signal output.

A selection circuit that amplifies and outputs a selected analog signal by arbitrarily selecting a signal to be input into an amplifier without waveform distortion is disclosed (see, for example, Japanese Patent Application Laid-open Publication No. H10-303656). This selection circuit includes a first switching unit disposed with plural switches to selectively pass plural analog signals input thereto respectively, and an amplifying circuit that amplifies the analog signals that pass through the first switching unit. The selection circuit further includes a bias circuit that adjusts an input voltage of the amplifying circuit to a desired value based on a reference voltage, and the bias circuit is connected to each input terminal of the switches.

However, the following problem arises with the conventional selection circuit with respect to the second switch group 5 shown in FIG. 1. When resistance values of the first to the third input resistors 16 to 18 and the feedback resistor 8 all equal R1, the gain of the differential input amplifier 7 becomes one-fold, and the signal sv1 is output at a gain of one-fold. In contrast, in view of the input side from the inverting input terminal of the differential input amplifier 7, three resistors R1 are connected in parallel. As a result, the input resistance with respect to the inverting input terminal of the differential input amplifier 7 becomes one third of R1 (R 1/3).

Therefore, assuming that nva is input reduced noise of the differential input amplifier 7 and present at a non-inverting input terminal of the differential input amplifier 7, a signal V (OUT) expressed by the following equation (1) is output to the output terminal (OUT) 9. In other words, the gain with respect to the signal sv1 is one-fold, while a noise gain with respect to noise of the differential input amplifier 7 becomes four-fold, resulting in reduction of signal-to-noise performance.

$$\begin{matrix}V ( OUT ) = - \frac{R 1}{R 1} ( sv 1 ) + \frac{( R 1 + \frac{1}{3} ) + R 1}{( R 1 \times \frac{1}{3} )} ( nva ) \\ = - sv 1 + nva \times 4 \end{matrix} \} \qquad ( 1 )$$

When the second switch group 5 is removed to prevent the reduction of the signal-to-noise performance, the noise leaking into the open switch in the first switch group 4 can not flow into the signal ground. Therefore, it is necessary to reduce the noise as much as possible.

Conventionally, each switch 10 to 12 in the first switch group 4, each input resistor 16 to 18 in the input resistor group 6, the differential input amplifier 7, and the feedback resistor 8 are formed on an identical semiconductor substrate. Each switch 10 to 12 includes a metal oxide semiconductor (MOS) transistor. The MOS transistor is formed in a well region to be connected to a power source or a ground.

Therefore, when a signal source and the selection circuit are formed on an identical semiconductor substrate, noise superimposed on well electric potential may leak into the switch through parasitic resistance or parasitic capacitance between each electrode of a source, a drain, and a gate, and the well region of the off MOS transistor, causing the primary factor of noise leaking into the open switch.

When the size of the MOS transistor is reduced, the parasitic resistance becomes larger and the parasitic capacitance becomes smaller, enabling reduction of the noise leaking into the signal path through the parasitic element. However, conduction resistance becomes larger, and the value of the conduction resistance cannot be disregarded with respect to each value of the resistances in the input resistor group 6 connected to the MOS transistor in series.

Since the conduction resistance of the MOS transistor varies depending on the voltage between the gate and the source, the input resistance of the differential input amplifier 7 varies depending on the gate-source voltage. As a result, the amplitude of the signal output from the differential input amplifier 7 varies, and the waveform of the signal to be amplified is distorted. In other words, the input and output gain of the selection circuit varies depending on the signal level, reducing signal quality.

Therefore, there is a limit in the extent that the size of the MOS transistor constituting the switch and the noise leaking into the switch can be reduced. Thus, it has been conventionally difficult to reduce the noise leaking into the signal path and the noise included in the output signal from the amplifier.

### SUMMARY

It is an aspect of the embodiments discussed herein to provide a selection circuit including a first switching unit that selects and outputs a first signal from among a plurality of analog signals input thereto; a second switching unit that outputs a second signal from a reference voltage supplied therein; and an amplifier that adds the first signal and the second signal.

The other objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a schematic of a conventional selection circuit;

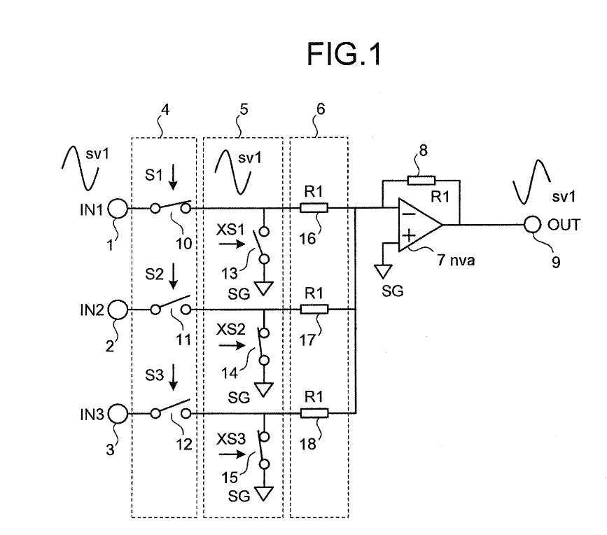

FIG. 2 is a schematic of a selection circuit according to a first embodiment;

FIG. 3 is a schematic of an equivalent circuit of semiconductor elements included in a switch of the selection circuit;

FIG. 4 is a schematic of a planer layout of the semiconductor elements; and

FIG. 5 is a schematic of a selection circuit according to a second embodiment.

### DETAILED DESCRIPTION OF THE PREFERRED EMBODIMENTS

Referring to the accompanying drawings, exemplary embodiments according to the present invention are explained in detail below. Although a case in which there are three input analog signals is explained, the present invention is not limited thereto and is further applicable for more than three input analog signals. Hereinafter, like reference numbers represent like elements, and explanations thereof are omitted.

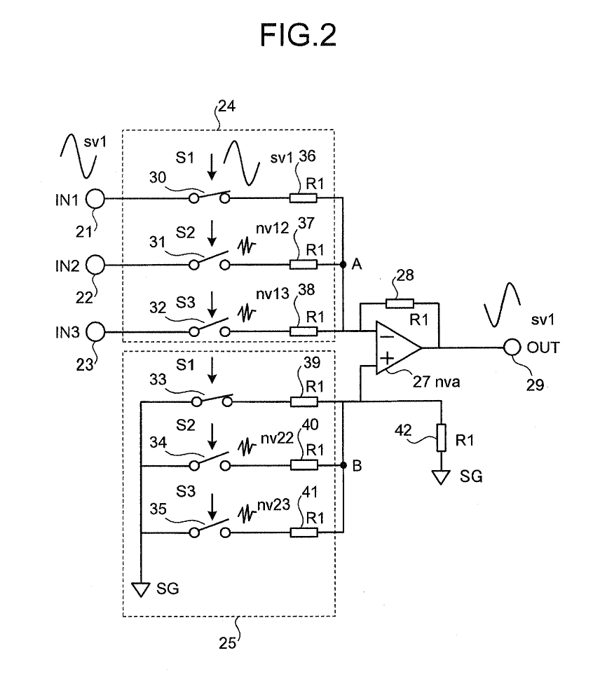

FIG. 2 is a schematic of a selection circuit according to a first embodiment. The selection circuit includes a first switching unit 24, a second switching unit 25, a differential input amplifier 27, a feedback resistor 28 of the differential input amplifier 27, a resistor 42, and an output terminal (OUT) 29. The first switching unit 24 includes a first to a third switch 30 to 32, and a first to a third input resistor 36 to 38. The second switching unit 25 includes a fourth to a sixth switch 33 to 35, and a fourth to a sixth input resistor 39 to 41.

The first to the third input terminals (IN1) 21 to 23 are connected, through the first to the third switches 30 to 32, to the first to the third input resistor 36 to 38 that are connected to a converting input terminal of the differential input amplifier 27, respectively. For simplicity, three signal paths in the first switching unit 24 are correspondingly called a first to a third path.

The fourth to the sixth input resistors 39 to 41 are connected, through the fourth to the sixth switches 33 to 35, to an analog reference voltage source SG at one end, and to a non-converting input terminal of the differential input amplifier 27 at the other end. For simplicity, three signal paths in the second switch 25 are correspondingly called a fourth to a sixth path.

Three pairs, respectively including the first and the fourth switches 30 and 33, the second and the fifth switches 31 and 34, the third and the sixth switches 32 and 35, are respectively controlled by selection signals S1 to S3 to become open or closed. One or more pairs of the switches become closed.

An output terminal of the differential input amplifier 27 is connected to the output terminal (OUT) 29. A feedback resistor 28 is connected between the output terminal and the converting input terminal of the differential input amplifier 27. The resistor 42 is connected between the non-converting input terminal and the voltage source SG. The resistor 42, based on a combination of the fourth to the sixth input resistors, divides an input signal to the non-converting input terminal.

Resistance values of the first to the sixth input resistors, a feedback resistor 28, and the resistor 42 are equally R1. Each respective pair of the first and the fourth switches 30 and 33, the second and the fifth switches 31 and 34, and the third and the sixth switches 32 and 35 includes MOS transistors having the same size, as explained hereinafter.

When the first and the fourth switches 30 and 33 are closed, and the second, the third, the fifth, and the sixth switches 31, 32, 34, and 35 are open, only an analog signal sv1 input to the input terminal (IN1) 21 is selected. The signal sv1 passes through the first path, is inversely amplified at a gain of 1 by the differential input amplifier 27 to be output to the output terminal (OUT) 29.

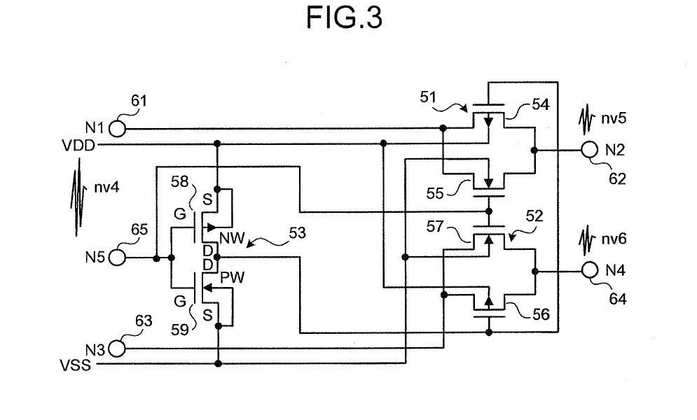

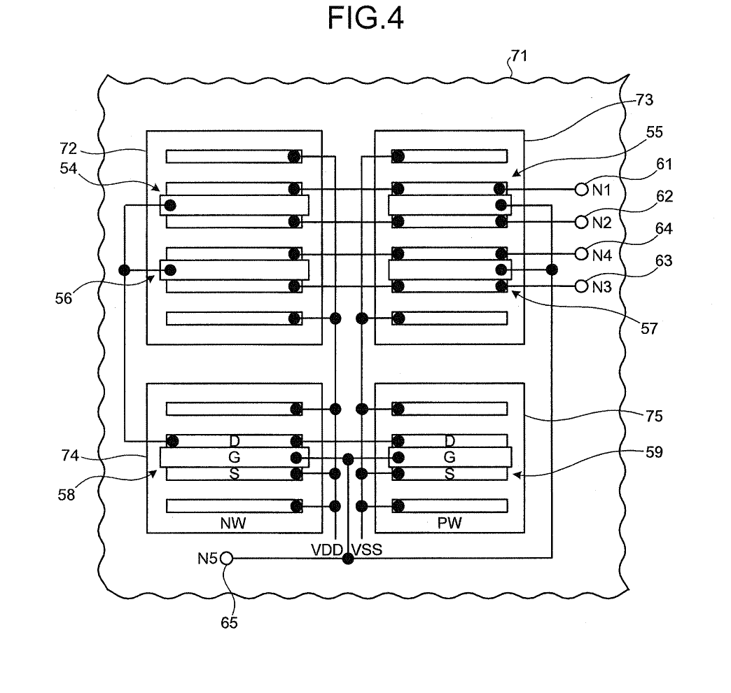

FIG. 3 is a schematic of an equivalent circuit of semiconductor elements included in the selection switch. FIG. 4 is a planar layout of the semiconductor elements. A configuration of a pair of switches including the first and the fourth switches 30 and 33 is shown in FIGS. 3 and 4. Configurations of other pairs, including the second and the fifth switches 31 and 34, and the third and the sixth switches 32 and 35, are similar to the configuration shown in FIGS. 3 and 4.

The pair including the first and the fourth switches 30 and 33 includes a switch unit 51 of the first switch 30, a switch unit 52 of the fourth switch, and an inverter 53. The switch unit 51 includes a PMOS transistor 54 and an NMOS transistor 55 that are connected in parallel between an input terminal (IN) 61 and an output terminal (N2) 62 of the first switch 30. The switch unit 52 includes a PMOS transistor 56 and an NMOS transistor 57 that are connected in parallel between the first input terminal 63 and an output terminal 64 of the fourth switch 33.

A gate terminal of the NMOS transistors 55 and 57 is connected to an input terminal (N5) 65 of the first selection signal S1. A gate terminal of the PMOS transistor 54 and 56 is connected to an output terminal of the inverter 53. An input terminal of the inverter 53 is connected to the input terminal (N5) 65.

When the first selection signal S1 is of a relatively high potential, the MOS transistors 54 to 57 become closed, and the first and the fourth switches become closed. In contrast, when the first selection signal S1 is of a relatively low potential, the first and the fourth switches 30 and 33 become open. Reference characters VDD and VSS respectively represent a power source and a ground.

The PMOS transistors 54 and 56 are formed in a first N-well region 72 on a semiconductor substrate 71. The NMOS transistors 55 and 57 are formed in a first P-well region 73 on the semiconductor substrate 71.

The output terminals (N2 and N4) 62 and 64 are arranged close to each other. As a result, noise leaking from the power source into the first and the fourth switches through the first N-well and the first P-well regions 72 and 73 become identical.

MOS transistors 58 and 59 of the inverter 53 are respectively formed in a second N-well and a second P-well region 74 and 75 on the semiconductor substrate 71. The first and the second N-well regions 72 and 74 are connected to the power source VDD through a contact region. The first and the second P-well regions 73 and 75 are connected to the ground VSS through the contact region.

The first to the sixth resistances 36 to 41, the differential input amplifier 27, the feedback resistor 28, and the resistor 42 are formed on a region that is not shown on the semiconductor substrate 71. In other words, the selection circuit according to the first embodiment is formed on a substrate identical to the semiconductor substrate 71. Reference characters “S”, “G”, “D”, “NW”, and “PW” shown in FIGS. 3 and 4 represent a source terminal (source electrode), a gate terminal (gate electrode), a drain terminal (drain electrode), an N-well, and a P-well, respectively.

Reference characters nv12, nv13, nv22, and nv23 shown in FIG. 2 respectively represent noise leaking into the open switches on the second to the sixth paths. Reference characters nv4, nv5, and nv6 shown in FIG. 3 respectively represent noise superimposed on the power source VDD, noise caused by the noise nv4 leaking when the switch unit 51 is open, noise caused by the noise nv4 leaking when the switch unit 52 is open. The noise nv5 and nv6 shown in FIG. 3 become the noise nv12 and nv22 for the pair of switches including the second and the fifth switches 31 and 34, and the noise nv13 and nv23 for the pair of switches including the third and the sixth switches 32 and 35.

Since the switches in the first and the second switching units 24 and 25 are controlled by the first to the third selection signals S1, S2, and S3, the number of open switches in the first switching unit 24 is equivalent to that in the second switching unit 25. As explained above, each MOS transistor in the first switching unit 24 has the same size as the corresponding MOS transistor in the second switching unit 25.

As a result of the arrangement shown in FIG. 3, the amount of noise of nv12 and nv13 becomes identical to the amount of noise of nv22 and nv23, respectively. Since the noises is added by the differential input amplifier 27 and cancelled, the noise is not output to the output terminal (OUT) 29. In other words, the reduction of the signal-to-noise performance caused by the noise through the parasitic element in the switch can be prevented.

The effect of the input reduced noise nva of the differential input amplifier 27 is explained. In FIG. 2, a voltage V(A) of an output node A of the first switching unit 24 and a voltage V(B) of an output node B of the second switching unit 25 are expressed by the following equation (2). As a result, a signal V (OUT) expressed by the following equation (3) is output to the output terminal (OUT) 29. Consequently, a gain with respect to the input signal sv1 is one-fold, while a noise gain of the differential input amplifier 27 is two-fold.

$$\begin{matrix}\begin{matrix}V ( A ) = V ( B ) \\ = \frac{R 1}{R 1 + R 1} ( nv 22 + nv 23 ) + nva \\ = \frac{1}{2} ( nv 22 + nv 23 ) + nva\end{matrix} \} & ( 2 ) \\ \begin{matrix}V ( OUT ) = V ( A ) \times \frac{R 1 + R 1}{R 1} - \frac{R 1}{R 1} ( sv 1 + nv 12 + nv 13 ) \\ = V ( A ) \times 2 - ( nv 12 + nv 13 + sv 1 ) \\ = ( nv 22 + nv 23 ) + nva \times 2 - ( nv 12 + nv 13 + sv 1 ) \\ = - sv 1 + nva \times 2 + ( nv 22 - nv 12 ) + ( nv 23 - nv 13 ) \\ = - sv 1 + nva \times 2 \\ ( ∵ nv 22 = nv 12 , v 23 = nv 13 )\end{matrix} \} & ( 3 )\end{matrix}$$

Thus, the noise gain of the differential input amplifier 27 becomes half that of the conventional differential input amplifier 7. Although this is a case in which one of the three analog input signals is selected, the noise gain varies depending on the number of the selected analog signals. For example, when the two pairs of switches including the first and the fourth switches 30 and 33, and the second and the fifth switches 31 and 34 are closed, a gain with respect to each of the signals input to the first and the second input terminals (IN1 and IN2) 21 and 22 becomes one-fold, and the noise gain becomes three-fold.

When the three pairs of switches including the first and the fourth switches 30 and 33, the second and the fifth switches 31 and 34, the third and the sixth switches 32 and 35 are closed, a gain with respect to each of the input signals becomes one-fold, and the noise gain becomes four-fold. Thus, when the number of the selected signals is M, the noise gain becomes (M+1) fold. The same can apply to a case in which M is four or more. When plural signals are selected, the selected plural signals are added by the differential input amplifier 27 to be output to the output terminal (OUT) 29.

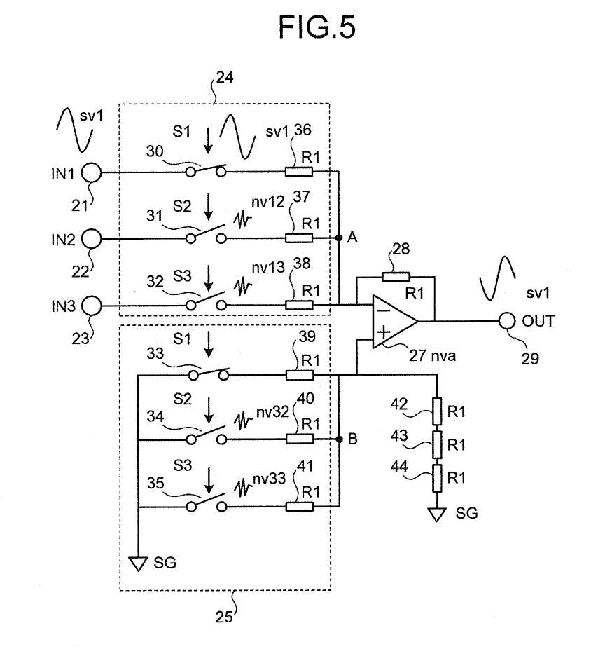

FIG. 5 is a schematic of a selection circuit according to a second embodiment. In the second embodiment, the selection switch according to the first embodiment is modified such that each MOS transistor in the first switching unit 24 has a size that differs from the corresponding MOS transistor in the second switching unit 25. Hereinafter, a size of each of the fourth to the sixth switches 33 to 35 is approximately two thirds of that of each of the first to the third switches 30 to 32.

In this case, a value of the resistance between the non-converting input terminal and the power source SG becomes triple that in the first embodiment. To demonstrate this, resistances 43 and 44 are connected to the resistor 42 in series. Resistance values of the resistances 42 to 44 are equally R1. From the perspective of the output terminal (OUT) 29, noises leaking into the first and the second switching units 24 and 25 have the same values and different polarities.

As a result, this noise is not output to the output terminal (OUT) 29. The second embodiment has a merit in that the switch occupies a smaller area on the semiconductor substrate. Although the conduction resistance of each switch becomes larger in the second embodiment, the increased conduction resistance is not problematic since the signal input to each switch in the second switching unit 25 is a constant direct voltage that does not greatly vary in amplitude.

The effect of the input reduced noise nva of the differential input amplifier 27 is explained. In FIG. 5, a voltage V(A) of an output node A of the first switching unit 24 and a voltage V(B) of an output node B of the second switching unit 25 are expressed by the following equation (4). As a result, a signal V (OUT) expressed by the following equation (5) is output to the output terminal (OUT) 29. Consequently, a gain with respect to the input signal sv1 is one-fold, while a noise gain of the differential input amplifier 27 is two-fold in a similar manner as the first embodiment.

$$\begin{matrix}\begin{matrix}\begin{matrix}V ( A ) = V ( B ) \\ = \frac{( R 1 ) \times 3}{( R 1 ) \times 3 + R 1} ( nv 32 + nv 33 ) + nva\end{matrix} \\ = \frac{3}{4} ( nv 22 + nv 23 ) + nva \end{matrix} \} & ( 4 ) \\ \begin{matrix}\begin{matrix}V ( OUT ) = V ( A ) \times \frac{R 1 + R 1}{R 1} - \frac{R 1}{R 1} ( sv 1 + nv 12 + nv 13 ) \\ = V ( A ) \times 2 - ( nv 12 + nv 13 + sv 1 ) \\ = ( nv 32 + nv 33 ) \times \frac{3}{2} + nva \times 2 - ( nv 12 + nv 13 + sv 1 )\end{matrix} \\ \begin{matrix} = - sv 1 + nva \times 2 + ( nv 32 \times \frac{3}{2} - nv 12 ) + \\ ( nv 33 \times \frac{3}{2} - nv 13 ) \\ = - sv 1 + nva \times 2 \\ ( ∵ nv 32 = nv 12 \times \frac{2}{3} , nv 33 = nv 13 \times \frac{2}{3} )\end{matrix}\end{matrix} \} & ( 5 )\end{matrix}$$

In the above embodiments, it is preferable that the gain of each path in first switching unit 24 and the gain of each path in the second switching unit 25 are substantially identical. In this case, it is preferable that the number of the closed switches in the first switching unit 24 is equivalent to that in the second switching unit 25. Alternatively, the size of each MOS transistor included in the switch in the second switching unit 25 may be one N-th of that of each MOS transistor included in the switch in the first switching unit 24, where N is a positive real number. In this case, it is preferable that the gain of each path in the second switching unit 25 is as approximately N times as that of each path in the first switching unit 24.

Furthermore, the MOS transistors and resistances in the first and the second switching units 24 and 25, and the amplifier 27 may be formed on an identical semiconductor substrate. The MOS transistor may be an N type, a P type, or a complementary type of the N and the P types. The identical-type MOS transistors may be formed on an identical well region.

According to the above embodiments, the noises leaking into the first and the second switching units 24 and 25 are added by the amplifier 27, resulting in reduction of the noise output from the selection circuit. When gains of the first and the second switching units 24 and 25 are substantially identical, and the number of closed switches in the first and the second switching units 24 and 25 are equivalent, noises leaking into the paths through open parasitic elements in the first and the second switching units 24 and 25 become identical. Therefore, the noises leaking into the paths in the first and the second switching units 24 and 25 are cancelled by the amplifier 27.

Furthermore, even if the size of the MOS transistors are different between the first and the second switching units 24 and 25, the noise leaking into the each path through the open parasitic element in each switch unit becomes identical by adjusting each gain. Therefore, the noises leaking into the paths in the first and the second switching units 24 and 25 are cancelled by the amplifier 27. Furthermore, the area occupied by the selection circuit can be reduced by making the size of either the first or the second switching unit 24 or 25 one N-th of the other switching unit 24 or 25.

Furthermore, when the first switching unit 24 selects one signal and a gain thereof is one, the noise gain of the amplifier 27 with respect to the input reduced noise becomes two. In other words, regardless of the number of the signals input to the selection circuit is, as long as one signal is selected by the first switching unit 24, the noise gain becomes as twice the signal gain.

According to the embodiments explained above, the noise leaking into each switch through the parasitic capacitance and the parasitic resistance thereof, and the noise gain of the amplifier 27 can be reduced. Furthermore, more than one signal can be selected from among plural analog input signals and output by adding the selected signals.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A selection circuit comprising:
a first switching unit that selects and outputs a first signal from among a plurality of analog signals input thereto;
a second switching unit that outputs a second signal from a reference voltage supplied therein; and
an amplifier that adds the first signal and the second signal.

2. The selection switch according to claim 1, wherein
the first switching unit includes a plurality of first paths through which the analog signals pass, respectively,
the second switching unit includes a plurality of second paths supplied with the reference voltage and equivalent in number to the first paths, and
gains of the first paths are identical to gains of the second paths, respectively.

3. The selection switch according to claim 2, wherein
the first switching unit includes a plurality of first switches that are provided on the first paths and switch the first paths between a closed-state and an open-state, respectively,
the second switching unit that includes a plurality of second switches that are provided on the second paths and switch the second paths between a closed-state and an open-state, respectively, and
the first switches in the closed-state and the second switches in the closed-state are equivalent in number.

4. The selection switch according to claim 1, wherein
the first switching unit includes a plurality of first switches including NMOS transistors or PMOS transistors, and a plurality of first resistors connected in series with the first switches, respectively, and
the NMOS transistors or the PMOS transistors, the first resistors, and the amplifier are formed on a semiconductor substrate.

5. The selection switch according to claim 4, wherein the second switching unit is formed on the semiconductor substrate, and includes a plurality of second switches each having a configuration identical to that of the first switches and a plurality of second resistors connected in series with the second switches, respectively.

6. The selection switch according to claim 1, wherein
the first switching unit includes a plurality of first switches that include complementary-type MOS transistors each having an NMOS transistor and a PMOS transistor, and a plurality of first resistors connected in series with the first switches, respectively, and
the complementary-type MOS transistors, the first resistors, and the amplifier are formed on a semiconductor substrate.

7. The selection switch according to claim 6, wherein the second switching unit is formed on the semiconductor substrate, and includes a plurality of second switches each having a configuration identical to that of the first switches, and a plurality of second resistors connected in series with the second switches, respectively.

8. The selection switch according to claim 7, wherein NMOS transistors are formed on a well, and PMOS transistors are formed on another well.

9. The selection switch according to claim 5, wherein
the first switching unit includes a plurality of first paths through which the analog signals pass, respectively,
the second switching unit includes a plurality of second paths that are supplied with the reference voltage and equivalent in number to the first paths,
a size of each of the NMOS transistors or the PMOS transistors in the second switching unit is one N-th of that of the NMOS transistors or the PMOS transistors in the first switching unit, and
gain of each of the second paths is approximately N times that of each of the first paths, where N is a positive real number.

10. The selection switch according to claim 7, wherein
the first switching unit includes a plurality of first paths through which the analog signals pass, respectively,
the second switching unit includes a plurality of second paths that are supplied with the reference voltage, and equivalent in number to the first paths,
a size of each of the complementary-type MOS transistors in the second switching unit is one N-th of that of the complementary-type MOS transistors in the first switching unit, and
gain of each of the second paths is approximately N times that of each of the first paths, where N is a positive real number.
